(19) United States
(12) Patent Application Publication
(10) Pub. No.: US 2008/0279396 A1
(43) Pub. Date: Nov. 13, 2008

(54) AMPLIFIER REMOTE CONTROLLABLE AT A FRONT AND A REAR SIDE

(76) Inventor: Te-Wei Kung, Chia-Yi City (TW)

Correspondence Address: Te-Wei KUNG, P.O. BOX 90, Tainan City, 70499, TW

(21) Appl. No.: 11/746,073

(22) Filed: May 9, 2007

(51) Int. Cl. H03G 1/02

(52) U.S. Cl. 381/105

(57) ABSTRACT

An amplifier remote-controllable at a front and a rear side includes a speaker located at a front portion, an operational panel located at a rear portion, a CD player, an MP3 player, a battery base, a remote-controlled rear infrared receiver, and a remote-controlled front infrared receiver connected to the remote-controlled rear infrared receiver and located at the front portion. A user, whether standing at the front or the rear side of the amplifier, can use a remote controller to transmit signal to either of the two remote-controlled infrared receivers to operate the amplifier.

### BACKGROUND OF THE INVENTION

1. Field of the Invention

This invention relates to an amplifier remote-controllable at a front and a rear side, particularly to one possible to be operable from the front side or the rear side of the amplifier, without necessity of turning manually the direction of the amplifier, by means of a remote-controlled rear infrared receiver properly connected to a CD player of the amplifier. The remote-controlled rear infrared receiver is also connected to a remote-controlled front infrared receiver. Therefore, a user can uses a remote controller to transmit signal to either of the two remote-controlled infrared receivers to operate the amplifier, whether standing at a front side or the rear side of the amplifier.

2. Description of the Prior Art

A conventional amplifier remote-controllable from a rear side of the amplifier 1, as shown in FIGS. 1 and 2, includes a speaker 10 located at a front portion, an operational panel 11 located at a rear portion, a CD player 12, an MP3 player 13, a battery base 14 and a remote-controlled rear infrared receiver 15 properly connected to the CD player 12.

In using, in order to operate the amplifier from a rear side, a user has to turn manually the amplifier to face the rear side, or walk to the rear side of the amplifier 1, and then transmit signal from a remote controller 2 to the remote-controlled rear infrared receiver 15. Then the amplifier can be operated to work, practically inconvenient for using.

### SUMMARY OF THE INVENTION

This invention has been devised to offer an amplifier remote controllable at a front and a rear side.

The main feature of the invention is a remote-controlled rear infrared receiver, which is connected to a remote-controlled front infrared receiver located at a front portion of the amplifier.

### BRIEF DESCRIPTION OF DRAWINGS

This invention will be better understood by referring to the accompanying drawings, wherein:

FIG. 1 is a block diagram of the circuit of a conventional amplifier remote-controllable at a rear side;

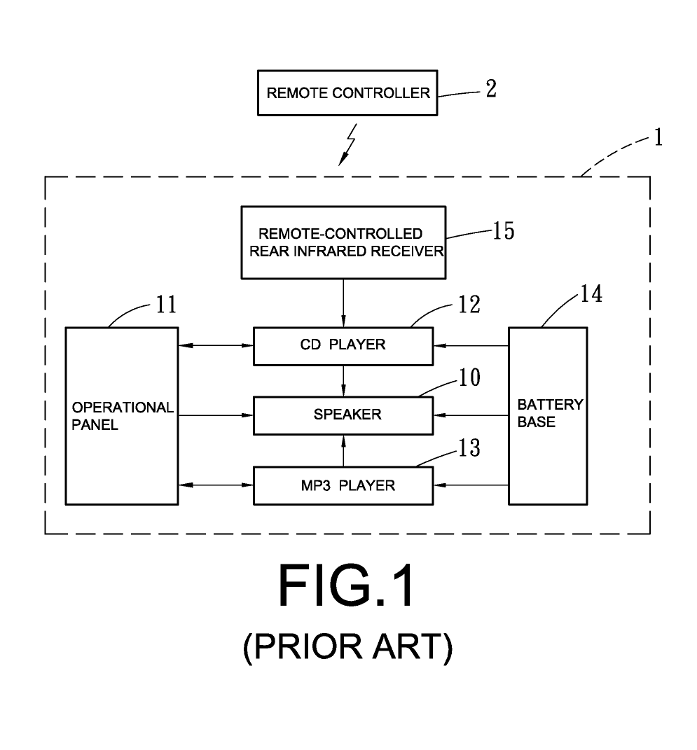

FIG. 2 is a perspective view of the conventional amplifier remote controllable at the rear side being used;

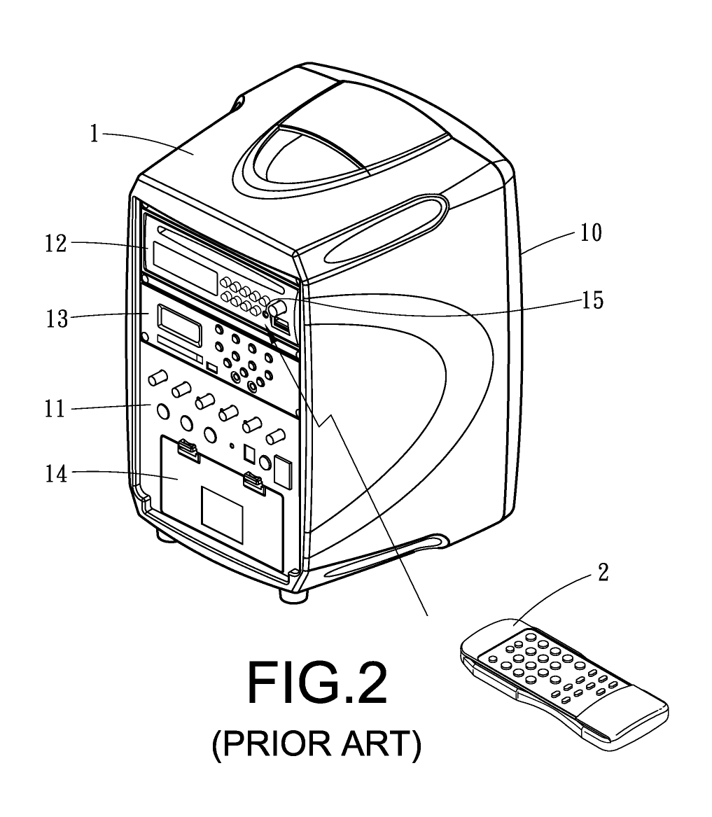

FIG. 3 is a block diagram of the circuit of an amplifier remote-controllable at a rear side and a rear side in the present invention;

FIG. 4 is a perspective view of the amplifier remote-controllable at a front and a rear side in the present invention, showing it used in one way; and,

FIG. 5 is a perspective view of the amplifier remote-controllable at a front and a rear side in the present invention, showing it used in another way.

### DETAILED DESCRIPTION OF THE PREFERRED EMBODIMENT

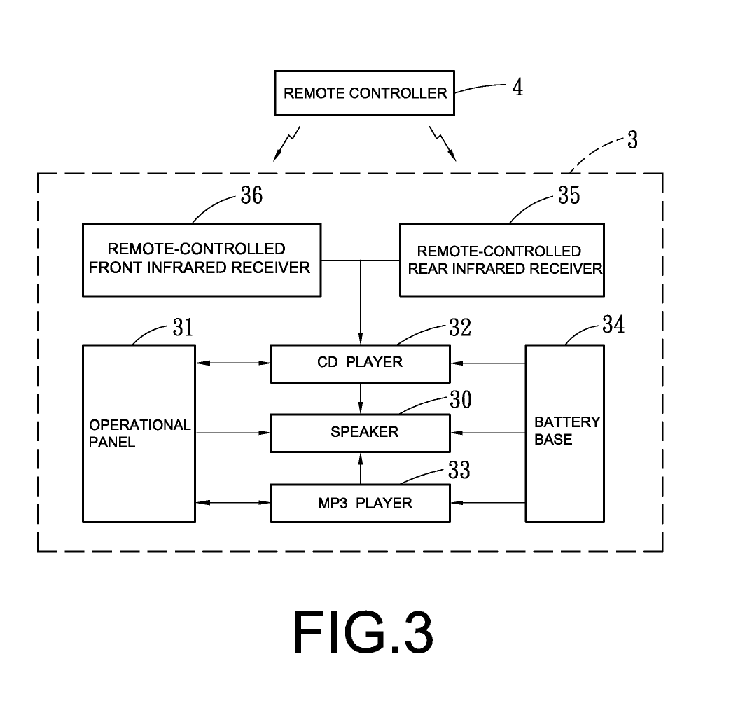

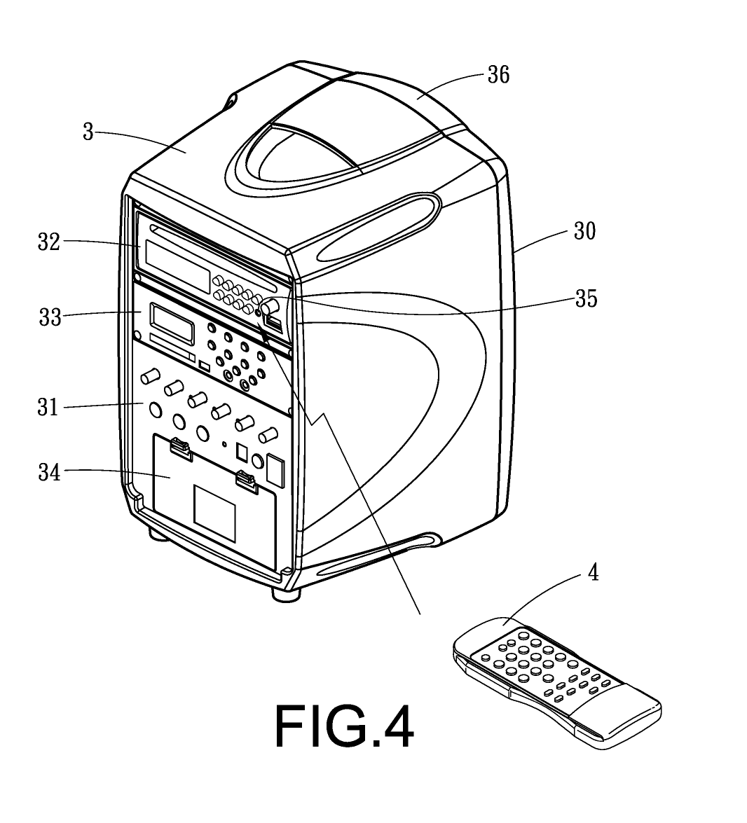

A preferred embodiment of an amplifier remote-controllable at a front and a rear side in the present invention, as shown in FIGS. 3 and 4, includes a speaker 30 located at a front portion, a operational panel 31 located at a rear portion, a CD player 32, an MP3 player 33, a battery base 34, a remote-controlled rear infrared receiver 35 located at the rear portion and connected properly to the CD player 32, and a remote-controlled front receiver 36 located at the front portion and connected to the remote-controlled rear infrared receiver 35.

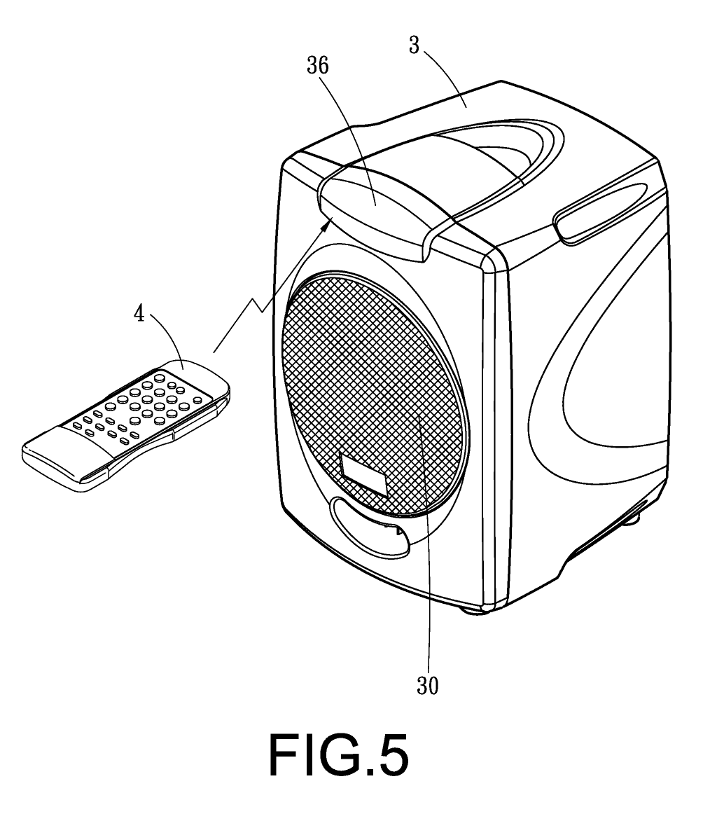

In using, as shown in FIGS. 3, 4 and 5, if a user stands at the rear side of the amplifier 3, he can use a remote controller 4 to transmit signal to the remote-controlled rear infrared receiver 35. On the contrary, it the user stands at the front side of the amplifier 3, he can used the remote controller 4 to transmit signal to the remote-controlled front infrared receiver 36 for operating the amplifier 3. So the user does not need to turn the direction of the amplifier 3, whether he stands at the front or the rear side of the amplifier 3, convenient to use it.

While the preferred embodiment has been described above, it will be recognized and understood that various modifications may be made therein and the appended claimed are intended to cover all such modifications that may fall within the spirit and scope of the invention.

What is claimed is:

1. An amplifier remote-controllable at a front and a rear side, said amplifier comprising a speaker located at a front portion, an operational panel located at a rear portion, a CD player, an MP3 player, a battery base, and a remote-controlled rear infrared receiver located at the rear portion: and,
characterized by a remote-controlled front infrared receiver connected to said remote-controlled rear infrared receiver and located at the front portion of said amplifier.
